(19) United States
(12) Patent Application Publication
(10) Pub. No.: US 2004/0063035 A1
(43) Pub. Date: Apr. 1, 2004

(54) Stereolithographic resin composition comprising photo-curable component, sol-gel resin and filler and stereolithographic method using the same

(75) Inventors: Kazuhiko Nagano, Kanagawa (JP); Yoji Okazaki, Kanagawa (JP); Takeshi Fujii, Kanagawa (JP); Hiromi Ishikawa, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 10/670,608

(22) Filed: Sep. 26, 2003

(30) Foreign Application Priority Data
Sep. 30, 2002 (JP) 2002-287933

(51) Int. Cl. G03F 7/029; B29C 67/00; C 08L 1 1/16

(52) U.S. Cl. 430/283.1; 430/322; 430/269; 430/285.1; 430/284.1; 430/288.1; 430/910; 430/280.1; 264/401; 522/77; 522/71; 522/116; 522/117; 522/121

(57) ABSTRACT

The invention provides a stereolithographic resin composition including a photo-curable component, a resin having a function of causing a reversible, quick sol-gel phase transition based on temperature change, and a filler, and a stereolithographic method using the resin composition.

CROSS-REFERENCE TO RELATED APPLICATION

This application claims priority under 35 USC 119 from Japanese Patent Application No. 2002-287933, the disclosure of which is incorporated by reference herein.

### BACKGROUND OF THE INVENTION

1. Field of the Invention

The present invention relates to a stereolithographic resin composition and a stereolithographic method using the same. More particularly, the invention relates to a stereolithographic resin composition suitable for use in formation of a three-dimensional object and a stereolithographic method using the same.

2. Description of the Related Art

As 3-D CAD (Computer Aided Design) systems spread, a stereolithographic system which forms a three-dimensional model based on a three-dimensional configuration produced by 3-D CAD in a virtual space on a computer is used, and the model formed by irradiating a light beam onto a stereolithographic resin composition in accordance with CAD data. The stereolithographic system forms the three-dimensional model by slicing, on the computer, the CAD data of the model at predetermined intervals to generate a plurality of cross-sectional data pieces, scanning the surface of the stereolithographic resin composition liquid with laser light based on each of the cross-sectional data pieces to thereby cure the resin surface into layers, and sequentially laminating the photo-cured layers to thereby form the three-dimensional model.

For example, Japanese Patent Application Laid Open (JP-A) No. 56-144478 (pages 1-2) discloses a method for stereolithographically forming a three-dimensional object. The method includes the steps of: introducing a stereolithographic resin composition liquid into a container; operating light irradiation means disposed above the container for selective light irradiation on the surface of the stereolithographic resin composition, thereby forming a photo-cured layer; feeding an additional amount of the stereolithographic resin composition onto the photo-cured layer, thereby forming a liquid resin layer thereon; selectively irradiating light onto the surface of the resin layer, thereby laminating another photo-cured layer on the previously cured layer to integrate them; and repeating feeding of a further additional amount of the stereolithographic resin composition and light irradiation until a desired object can be obtained.

In the above-mentioned method, however, an uncured portion is liquid and does not have mechanical strength for supporting the cured portion. Accordingly, the method has a drawback in that, for example, when an object in which an upper portion thereof is larger than a lower portion thereof is formed, the upper portion tends to deform (e.g. warp). To solve this problem, complicated steps are required which include forming an extra support portion for supporting the large upper portion and removing the support portion from a pre-formed object.

As a solution to the above-described problem, an invention has been disclosed which utilizes a stereolithographic resin composition containing a resin which causes a reversible, quick sol-gel phase transition based on temperature change (see, for example, JP-A No. 2001-49129, pages 2-3). According to the invention, a resin in a gel phase is photo-cured to form a photo-cured layer. Hence, when an upper portion of the object is larger than a lower portion of the object, the disclosed invention does not require a support portion and enables quick stereolithographic formation of the object.

However, the object made of such a stereolithographic resin composition containing the resin which causes the sol-gel phase transition warps by polymerization heat at the time of photo-curing.

While a stereolithographic resin composition containing a filler component for the purpose of improving the mechanical and thermal properties of the stereolithographically formed object has been disclosed (see, for example, JP-A No. 8-183820, page 2).

In some cases, however, the invention cannot achieve the intended improvement of the properties because the composition is liquid and the filler component tends to settle.

Therefore, there is a need for a stereolithographic resin composition which contains a resin that causes the sol-gel phase transition and which can provide a stereolithgraphically formed object that dose not warp when subjected to polymerization heat at the time of photo-curing.

Moreover, there is a need for a stereolithographic resin composition containing a filler which stereolithographic resin composition prevents sedimentation of the filler.

Also, there is a need for a stereolithographic method using the stereolithographic resin composition capable of solving the above problems.

### SUMMARY OF THE INVENTION

A first aspect of the invention is to provide a stereolithographic resin composition comprising a photo-curable component, a sol-gel resin material having a function of causing a reversible, quick sol-gel phase transition based on temperature change, and a filler.

A second aspect of the invention is to provide a stereolithographic method comprising the steps of: forming a first layer of a stereolithographic resin composition, imagewise exposing the first layer to light to at least partially cure the first layer, forming a second layer of the stereolithographic resin composition on the cured first layer, imagewise exposing the second layer to light to integrate at least a portion of the second layer to be cured with a cured portion of the first layer and to form a layered product including a cured portion and an uncured portion, and removing the uncured portion from the layered product to obtain a stereolithographically formed object, wherein the stereolithographic resin composition comprises a photo-curable component, a sol-gel resin material having a function of causing a reversible, quick sol-gel phase transition based on temperature change, and a filler.

When the stereolithographic resin composition containing a thermally conductive filler is used, an object with reduced heat distortion can be obtained and forming precision can be improved as compared with an object made of a resin composition free from the filler.

### BRIEF DESCRIPTION OF THE DRAWINGS

FIGS. 1A to 1G are sectional views showing the steps of the stereolithographic method of the invention.

### DETAILED DESCRIPTION OF THE INVENTION

A stereolithographic resin composition of the invention includes a photo-curable component, a sol-gel resin material having a function of causing a reversible, quick sol-gel phase transition based on temperature change, and a filler. The stereolithographic resin composition of the invention contains the sol-gel resin material and hence, the stereolithographic resin composition causes the reversible, quick sol-gel phase transition based on temperature change.

<Photo-Curable Component>

The photo-curable component contained in the stereolithographic resin composition of the invention may be any compound that contains, in the molecule, one or more functional group capable of causing a photo-reaction when exposed to light and thereby forming a crosslinking structure.

Examples of the photo-curable component include a radically polymerizable compound.

As the radically polymerizable compound, a compound containing at least one ethylenic unsaturated bond in the chemical structure thereof is preferable. Such a compound is preferably a monomer, a prepolymer (dimer, trimer or oligomer thereof), a mixture thereof or a copolymer thereof.

Specific examples of such a compound include an unsaturated carboxylic acid and salts thereof; an ester of an aliphatic polyhydric alcohol compound and an unsaturated carboxylic acid; and an amide of an aliphatic polyamine compound and an unsaturated carboxylic acid.

Specific examples of the unsaturated carboxylic acid include acrylic acid, methacrylic acid, itaconic acid, crotonic acid, isocrotonic acid, and maleic acid.

Specific examples of the salts of the unsaturated carboxylic acid include sodium and potassium salts of the above-mentioned unsaturated carboxylic acid.

Examples of the ester of the aliphatic polyhydric alcohol compound and the unsaturated carboxylic acid include acrylic ester, methacrylic ester, itaconic ester, crotonic ester, and isocrotonic ester. The esters will be described in more details.

Examples of the acrylic ester include ethylene glycol diacrylate, triethylene glycol triacrylate, 1,3-butanediol diacrylate, tetramethylene glycol diacrylate, propylene glycol diacrylate, trimethylolpropane triacrylate, trimethylolethane triacrylate, 1,4-cyclohexanediol diacrylate, pentaerythritol diacrylate, pentaerythritol triacrylate, pentaerythritol tetraacrylate, dipentaerythritol diacrylate, dipentaerythritol triacrylate, dipentaerythritol tetraacrylate, sorbitol triacrylate, sorbitol tetraacrylate, sorbitol pentaacrylate, sorbitol hexaacrylate, and polyester acrylate oligomer.

Examples of the methacrylic ester include tetramethylene glycol dimethacrylate, triethylene glycol dimethacrylate, trimethylolpropane trimethacrylate, trimethylolethane trimethacrylate, ethylene glycol dimethacrylate, 1,3-butanediol dimethacrylate, pentaerythritol dimethacrylate, pentaerythritol trimethacrylate, dipentaerythritol dimethacrylate, sorbitol tetramethacrylate, bis-[p-(3-methacryloxy-2-hydroxypropoxy)phenyl]dimethylmethane, and bis-[p-(acryloxyethoxy)phenyl]dimethylmethane.

Examples of the itaconic ester include ethylene glycol diitaconate, propylene glycol diitaconate, 1,3-butanediol diitaconate, 1,4-butanediol diitaconate, tetramethylene glycol diitaconate, pentaerythritol diitaconate, and sorbitol tetraitaconate.

Examples of the crotonic ester include ethylene glycol dicrotonate, tetramethylene glycol dicrotonate, pentaerythritol dicrotonate, and sorbitol tetracrotonate.

Examples of the isocorotonic ester include ethylene glycol diisocrotonate, pentaerythritol diisocrotonate, and sorbitol tetraisocrotonate. Examples of the maleic ester include ethylene glycol dimaleate, triethylene glycol dimaleate, pentaerythritol dimaleate, and sorbitol tetramaleate.

These esters may be used alone or in combination.

Specific examples of the amide of the aliphatic polyamine compound and the unsaturated carboxylic acid include methylenebis-acrylamide, methylenebis-methacrylamide, 1,6-hexamethylenebis-acrylamide, 1,6-hexamethylenebis-methacrylamide, diethylenetriamine trisacrylamide, xylylenebis acrylamide, and xylylenebis methacrylamide.

Besides the above-described compounds, a vinylurethane compound disclosed in Japanese Patent Application Publication (JP-B) No. 48-41708 can also be used. The compound contains two or more polymerizable vinyl groups per molecule and is obtained by adding a vinyl monomer represented by the following formula to a polyisocyanate compound containing two or more types of isocyanate groups per molecule:

H₂═C(R)COOCH₂(R)OH

wherein R represents H or CH₃.

Furthermore, a condensed compound of acrylic acid, methacrylic acid or a derivative thereof, and a high molecular compound containing a vinyl group or a vinylidene group, such as a high molecular compound having a hydroxyl group, an amino group, an epoxy group, an halogen atom or a sulfonyloxy group in the side chain can also be used.

Another example of the usable photo-curable component is a cationic polymerizable compound.

The cationic polymerizable compound may be an epoxy resin. A monomeric, dimeric, oligomeric or polymeric epoxy compound containing one or more epoxy group per molecule can be used as such. Examples of such an epoxy compound include a reaction product between bisphenol A and epichrolohydrin, and a reaction product between a low molecular weight phenol-formaldehyde resin and epichlorohydrin. Epoxy resins disclosed and used in U.S. Pat. No. 4,026,705 and British Patent No. 1,539,192 can also be used.

Above all, the radically polymerizable compounds are preferable as the photo-curable component from the viewpoint of photo-curing speed and physical properties of photo-cured material.

<Filler>

The type of the filler contained in the stereolithographic resin composition of the invention is not particularly limited. The filler incorporated in the stereolithographic resin composition contributes to improved mechanical strength, moisture resistance and heat resistance and a reduced linear expansion coefficient of the stereolithographically formed object. Furthermore, the filler reduces distortion resulting from shrinkage caused by the photo-curing reaction. As a result, the object can be formed with high precision.

In addition, when the filler is thermally conductive, the stereolithgraphically formed object has improved thermal conductivity. Therefore, when the resin composition is subjected to light irradiation on a line or area basis, reaction heat generated at the time of photo-curing the streolithographic resin composition can be effectively diffused and an object can be formed with high precision and has reduced heat distortion.

Examples of the filler include: 1) inorganic fine particles such as of aluminum hydroxide, magnesium hydroxide, magnesium carbonate, calcium silicate, calcium oxide, magnesium oxide, aluminum nitride, boron nitride, crystalline silica, amorphous silica, silicon carbide, alumina, clay, calcium carbonate and glass beads; 2) organic fine particles such as of crosslinked polystyrene, polymethyl methacrylate and polymethyl siloxane; 3) inorganic fiber whiskers such as of potassium titanate fiber, magnesium sulfate fiber, magnesium borate fiber, aluminum borate fiber and carbon fiber.

Above all, the thermally conductive fillers of alumina, aluminum nitride, boron nitride, and crystalline silica, which have high thermal conductivity, are preferable for the purpose of increasing the thermal conductivity of the stereolithographically formed object.

In the invention, the filler is incorporated in an amount of 50 to 400 parts by mass based on a total mass of 100 parts by mass of the photo-curable component and the sol-gel resin material to be described hereinafter. These fillers may be used alone or in combination.

<Sol-Gel Resin Material>

The sol-gel resin material contained in the stereolithographic resin composition of the invention is a resin having a function of causing a reversible, quick sol-gel phase transition based on temperature change.

Examples of the sol-gel resin having a function of causing a sol-to-gel phase transition with temperature decrease include a mixture of a syndiotactic polymethacrylic ester and an isotactic polymethacrylic ester. Specific examples of the syndiotactic polymethacrylic ester include syndiotactic polymethyl methacrylate, syndiotactic isobutyl polymethacrylate, syndiotactic benzyl polymethacrylate, and syndiotactic methallyl polymethacrylate. Specific examples of the isotactic polymethacrylic ester include isotactic polymethyl methacrylate.

When the mixture of the syndiotactic polymethacrylic ester and the isotactic polymethacrylic ester is used as the sol-gel resin, a preferable mixing ratio of the photo-curable component, the filler, the syndiotactic polymethacrylic ester and the isotactic polymethacrylic ester which are composition components for imparting the function of causing the reversible, quick sol-gel phase transition based on temperature change to the stereolithographic resin composition may be empirically determined. This is because it depends upon conditions including the type of the photo-curable component, the type and stereoregularity of the syndiotactic polymethacrylic ester, and the type and stereoregularity of the isotactic polymethacrylic ester.

Meanwhile, the sol-gel resin may be a resin causing a sol-to-gel phase transition with temperature increase. Examples of such a sol-gel resin include resins disclosed in JP-A Nos. 9-192469, 9-227329, 10-77201, 10-101518 and 11-169703.

<Photopolymerization Initiator>

The stereolithographic resin composition of the invention preferably contains a photopolymerization initiator. The type of photopolymerization initiator to be used is not limited. However, when the radically polymerizable compound is used as the photo-curable component, examples of the photopolymerization initiator include: 1) a carbonyl compound such as benzoin, α-methylbenzoin, anthraquinone, chloroanthraquinone and acetophenone; 2) a sulfur-containing compound such as diphenyl sulfide, diphenyl disulfide and dithiocarbamate; and 3) a polycyclic aromatic compound such as α-chloromethylnaphthalene and anthracene.

Meanwhile, when the cationic polymerizable compound is used as the photo-curable component, the photopolymerization initiator can be a photoacid generating agent which generates acid when exposed to light. Examples of the photoacid generating agent include an organic halogen compound, an onium salt, and a sulfonic ester.

The content of the photopolymerization initiator is 0.1 to 10 parts by mass and preferably 1 to 5 parts by mass based on the total mass of 100 parts by mass of the photo-curable component and the sol-gel resin material.

The photopolymerization initiator may be used in combination with a known photosensitizer.

The stereolithographic resin composition of the invention may further contain another filler (reinforcing agent), a plasticizer, a stabilizer, a coloring agent, a flame retardant, an antioxidant, and/or an antistatic agent.

<Stereolithographic Method>

The stereolithographic method of the invention includes the steps of forming a first layer of a stereolithographic resin composition, imagewise exposing the first layer to light to at least partially cure the first layer, forming a second layer of the stereolithographic resin composition on the cured first layer, imagewise exposing the second layer to light to integrate at least a portion of the second layer to be cured with a cured portion of the first layer and to form a layered product including a cured portion and an uncured portion, and removing the uncured portion from the layered product to obtain a stereolithographically formed object, and the stereolithographic resin composition is above-mentioned one.

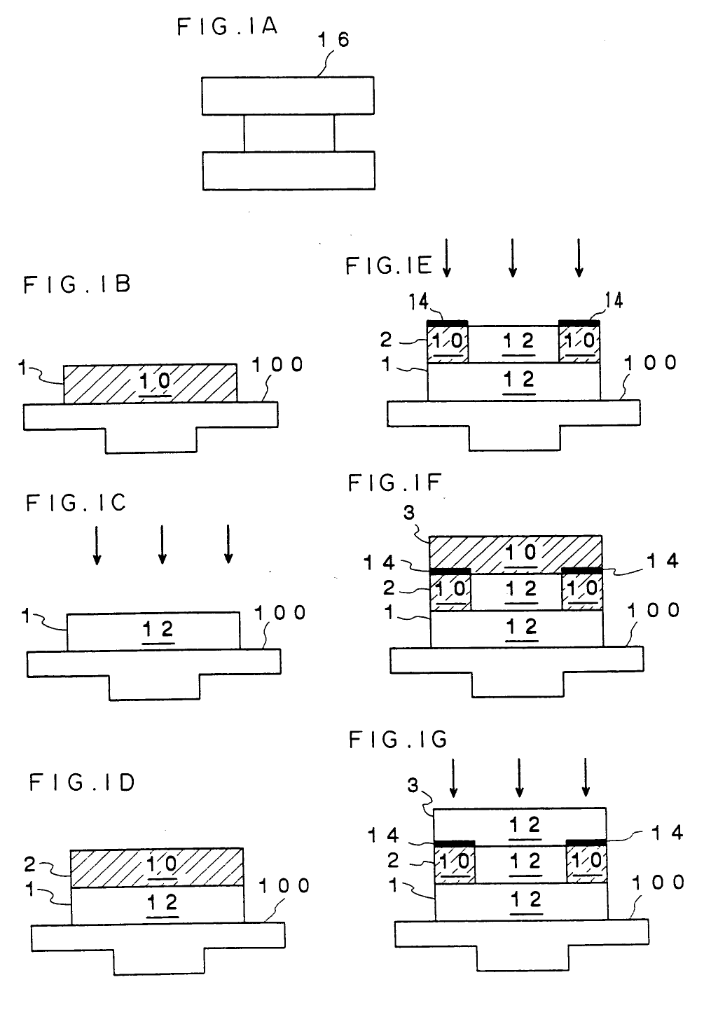

While referring to FIG. 1, an embodiment of the forming method of the invention will be described.

A stereolithographically formed object 16 shown in FIG. 1A may be formed according to the stereolithographic method of the invention as follows.

(1) As shown in FIG. 1B, a heated stereolithographic resin composition which is in a sol state is extruded onto an elevator 100 so as to form a layer 10 of uncured stereolithographic resin composition as a layer 1. In this step, the surface of layer 1 is preferably smoothed using unillustrated smoothing means. After the extrusion, the stereolithographic resin composition is cooled and becomes a gel.

(2) As shown in FIG. 1C, the layer 1 is exposed to light so as to form a photo-cured layer 12. After the light irradiation, the elevator 100 is lowered by the thickness of layer 1.

(3) As shown in FIG. 1D, another portion of the heated stereolithographic resin composition which is in a sol state is extruded onto the layer 1 so as to form another layer 10 of the uncured stereolithographic resin composition as a layer 2. In this step, the surface of layer 2 is preferably smoothed using the unillustrated smoothing means. After the extrusion, the stereolithographic resin composition is cooled and becomes a gel.

(4) As shown in FIG. 1E, a mask pattern 14 is placed on the surface of layer 2. Subsequently, the layer 2 is exposed to light so as to partially cure the layer 2. The portion of layer 2 not covered with the mask pattern 14 becomes a photo-cured layer portion 12 and the portions of layer 2 covered with the mask pattern 14 become layer portions 10 of the stereolithographic resin composition which is gel. After the light irradiation, the elevator 100 is lowered by the thickness of layer 2.

(5) As shown in FIG. 1F, a heated stereolithographic resin composition which is sol is extruded onto the layer 2 so as to form a layer of uncured stereolithographic resin composition as a layer 3. In this step, the surface of layer 3 is preferably smoothed by using the unillustrated smoothing means. After the extrusion, the stereolithographic resin composition is cooled and becomes a gel.

(6) As shown in FIG. 1G, the layer 3 is exposed to light so as to form a photo-cured layer 12 having an overhang portion. Thus, when the photo-cured layer having the overhang portion is formed, an additional step for forming support portions is not required. This is because the layer 2 includes the layer portions 10 of the stereolithographic resin composition which is gel and which serve as the support portions, directly under the overhang portion.

(7) A layered product obtained by the steps of (1) to (6) is taken off from the elevator 100 and then, the layer portions 10 of the uncured stereolithographic resin composition are removed from the layered product to obtain a stereolithographically formed object 16.

The uncured stereolithographic resin composition can be removed by heating it to make it sol and removing the sol. In order to remove the sol, the sol may be swelled by or dissolved in a solvent. After the removal, the resultant stereolithographically formed object may be rinsed with the solvent. After the removal of the uncured portions, the resultant stereolithographically formed object may be further exposed to light to secure complete curing of the resin composition, thereby further improving physical properties of the object, such as strength.

A light usable for the light irradiation depends upon the type of the photopolymerization initiator contained in the stereolithographic resin composition. Examples of light include infrared light, visible light and ultraviolet light. Among these, the ultraviolet light is preferable.

The material of the mask pattern 14 may be any material that can screen light used for light irradiation. In order to form the mask pattern directly on the layer 10 of the stereolithographic resin composition, the mask material may preferably be liquid in the light of easy application. In some cases, however, a powdery solid material may be used as the mask material.

When light is irradiated onto the stereolithographic resin composition via the mask pattern formed directly on the stereolithographic resin composition, the mask pattern is directly drawn on an exposure surface of the stereolithographic resin composition and then light is irradiated onto the composition via the mask pattern and another portion of the stereolithographic resin composition is fed to and laminated on the cured layer. This is because an ordinary photo-curable component is photo-cured with ultraviolet light. Therefore, the mask pattern must be fixed to the exposure surface of the resin composition and be thin (on the order of several microns) enough not to affect the height of the formed object.

As a mask forming method satisfying these conditions, an ink-jet printing method for ink-jet printers may preferably be employed. When the ink-jet printing method is adopted, ultrafine particles of a component which screens ultraviolet light and which is dispersed in a solvent may be used in place of an ink, and the component (ultraviolet screening component) may be titanium oxide.

Examples of the ultraviolet screening component include an inorganic material, such as ultrafine particles of titanium oxide, and an organic compound capable of absorbing ultraviolet light, such as polyglycidyl methacrylate. Compounds which are stabilized through intramolecular rearrangement induced by absorption of ultraviolet light and compounds containing a chromophore or auxochrome in an aromatic derivative, such as a 2-hydroxybenzophenone ultraviolet inhibitor, a triazole ultraviolet inhibitor, a salicylic derivative ultraviolet inhibitor, or an acrylonitrile derivative ultraviolet inhibitor, can also be used as the ultraviolet screening component.

Alternatively, a method in which light is irradiated onto the stereolithographic resin composition via a mask pattern (e.g., negative film) which is spaced apart from the composition, instead of using the mask pattern formed directly on the stereolithographic resin composition, and a method in which laser light is directly scanned on the stereolithographic resin composition without using the a mask pattern can be used.

If a liquid material is used as the stereolithographic resin composition, it is necessary to form a support portion at the time of formation of an overhang portion. Since the support portion is manually removed, a certain number of steps are required. It normally takes 6 to 12 hours to stereolithographically form a cubic object each side of which is 10 centimeters. When an object having a complicated configuration is formed, removal of the support portion requires the similar number of steps as those necessary for the stereolithographic formation of a layered product including unnecessary portions. However, the use of the stereolithographic resin composition of the invention does not need an additional step of forming the support portion because the portion directly under the overhang portion is gel.

The stereolithographic resin composition of the invention contains the filler component, preferably the thermally conductive filler component. Hence, the object stereolithographically formed from the stereolithographic resin composition of the invention has excellent properties including mechanical strength. Furthermore, the stereolithographic resin composition of the invention has the function of causing sol-gel phase transition. Therefore, the stereolithographic resin composition which is sol and extruded as a layer having a thickness of 0.025 to 0.2 mm is quickly cooled and becomes a gel upon contact with the underlying layer of the resin composition. Accordingly, the filler component contained in the stereolithographic resin composition is uniformly dispersed in the composition and does not settle. As a result, the effect of incorporating the filler component (improvement of mechanical strength) can be fully achieved.

In contrast, when the stereolithographic resin composition which is liquid is used, the filler component may settle after the extrusion step. In this case, the filler component is not uniformly dispersed in the composition and hence, it is hard to efficiently obtain the effect of incorporating the filler component.

### EXAMPLES

The invention will hereinafter be described in details while referring to an example thereof.

### Example 1

As the stereolithographic resin composition, a dispersion in which 50 parts by mass of alumina filler was dispersed in 100 parts by mass of resin composition including an urethane acrylate ultraviolet-curable resin, a syndiotactic polymethyl methacrylate and an isotactic polymethyl methacrylate at a weight ratio of 75:16.7:8.3 which was gel at a normal temperature but becomes a sol at about 80° C. was used.

When the stereolithographic resin composition was supplied, a predetermined amount of the composition stored in an extruder and heated at a temperature of 80° C. or more to make it sol was extruded onto an elevator and then leveled off with a recoater.

The composition fed into a container was cooled at a normal temperature. About 30 seconds later, the composition became a gel. The stereolithographic resin composition which was gel was imagewise exposed to light from an ultraviolet lamp and photo-cured. These steps were repeated and a layered product including unnecessary portions was obtained.

Thereafter, in order to remove uncured portions of the layered product, the layered product was heated at 80° C. in toluene for 3 hours while ultrasonic vibration was applied thereto. Finally, the resultant stereolithographically formed object was subjected to post exposure.

Since the stereolithographic resin composition containing the filler was used, heat distortion level was low. Therefore, the object could be formed more precisely than an object made of a stereolithographic resin composition which contained no filler.

### Comparative Example 1

An object was stereolithographically formed in the same manner as in Example 1, except that a composition containing 94 mass % of a cationic polymerizable compound, 5 mass % of a cationic photopolymerization initiator, and 1 mass % of a photo-cationic polymerization photosensitizer was used as the stereolithographic resin composition.

Using each of the compositions of Example 1 and Comparative Example 1, a frame-like structure having a nominal size of 100×100 mm was stereolithographically formed. The real size of each structure was measured to evaluate forming precision thereof.

The forming precision of the structure made of the composition used in Example 1 was superior to that of the structure made of the composition used in Comparative Example 1.

What is claimed is:

1. A stereolithographic resin composition comprising a photo-curable component, a sol-gel resin material having a function of causing a reversible, quick sol-gel phase transition based on temperature change, and a filler.

2. The stereolithographic resin composition of claim 1, wherein the filler is thermally conductive.

3. The stereolithographic resin composition of claim 1, wherein the photo-curable component includes at least one of a radically polymerizable compound and a cationic polymerizable compound.

4. The stereolithographic resin composition of claim 3, wherein the photo-curable component is selected from the group consisting of an unsaturated carboxylic acid and salts thereof, an ester of an aliphatic polyhydric alcohol compound and an unsaturated carboxylic acid, and an amide of an aliphatic polyamine compound and an unsaturated carboxylic acid.

5. The stereolithographic resin composition of claim 2, wherein the filler is selected from the group consisting of alumina, aluminum nitride, boron nitride and crystalline silica.

6. The stereolithographic resin composition of claim 1, wherein the content of the filler is in the range of 50 to 400 parts by mass with respect to a total mass of 100 parts by mass of the photo-curable component and the sol-gel resin material.

7. The stereolithographic resin composition of claim 1, wherein the sol-gel resin material comprises a mixture of a syndiotactic polymethacrylic ester and an isotactic polymethacrylic ester.

8. The stereolithographic resin composition of claim 1, further comprising a photopolymerization initiator.

9. The stereolithographic resin composition of claim 8, wherein the content of the photopolymerization initiator is in the range of 0.1 to 10 parts by mass with respect to a total mass of 100 parts by mass of the photo-curable component and the sol-gel resin material.

10. The stereolithographic resin composition of claim 1, wherein the photo-curable component comprises an ultraviolet curable resin.

11. A stereolithographic method comprising the steps of: forming a first layer of a stereolithographic resin composition, imagewise exposing the first layer to light to at least partially cure the first layer, forming a second layer of the stereolithographic resin composition on the cured first layer, imagewise exposing the second layer to light to integrate at least a portion of the second layer to be cured with a cured portion of the first layer and to form a layered product including a cured portion and an uncured portion, and removing the uncured portion from the layered product to obtain a stereolithographically formed object,
wherein the stereolithographic resin composition comprises a photo-curable component, a sol-gel resin material having a function of causing a reversible, quick sol-gel phase transition based on temperature change, and a filler.

12. The stereolithographic method of claim 11, wherein the filler is thermally conductive.

13. The stereolithographic method of claim 11, wherein the photo-curable component includes at least one of a radically polymerizable compound and a cationic polymerizable compound.

14. The stereolithographic method of claim 13, wherein the photo-curable component is selected from the group consisting of an unsaturated carboxylic acid and salts thereof, an ester of an aliphatic polyhydric alcohol compound and unsaturated carboxylic acid, and an amide of an aliphatic polyamine compound and an unsaturated carboxylic acid.

15. The stereolithographic method of claim 12, wherein the filler is selected from the group consisting of alumina, aluminum nitride, boron nitride and crystalline silica.

16. The stereolithographic method of claim 11, wherein the content of the filler is in the range of 50 to 400 parts by mass with respect to a total mass of 100 parts by mass of the photo-curable component and the sol-gel resin material.

17. The stereolithographic method of claim 11, wherein the sol-gel resin material comprises a mixture of a syndiotactic polymethacrylic ester and an isotactic polymethacrylic ester.

18. The stereolithographic method of claim 11, wherein the stereolithographic resin composition further comprises a photopolymerization initiator.

19. The stereolithographic method of claim 18, wherein the content of the photopolymerization initiator is in the range of 0.1 to 10 parts by mass with respect to a total mass of 100 parts by mass of the photo-curable component and the sol-gel resin material.

20. The stereolithographic method of claim 11, wherein the photo-curable component comprises an ultraviolet-curable resin.
